(19) United States
(12) Patent Application Publication
(10) Pub. No.: US 2010/0263713 A1
(43) Pub. Date: Oct. 21, 2010

(54) Four Terminal Monolithic Multijunction Solar Cell

(75) Inventor: Michael J. Ludowise, San Jose, CA (US)

Correspondence Address: THE MUELLER LAW OFFICE, P.C., 12951 Harwick Lane, San Diego, CA, 92130, US

(73) Assignee: SOLFOCUS, INC., Mountain View, CA (US)

(21) Appl. No.: 12/573,142

(22) Filed: Oct. 4, 2009

Related U.S. Application Data
(63) Continuation-in-part of application No. 12/424,658, filed on Apr. 16, 2009.

(51) Int. Cl. H01L 31/042; H01L 31/18

(52) U.S. Cl. 136/249; 438/73; 257/E21.158

(57) ABSTRACT

A monolithic multijunction photovoltaic device is disclosed which comprises two or more photovoltaic cells between two surfaces. Each of the photovoltaic cell materials include a first region exhibiting an excess of a first charge carrier and a second region exhibiting an excess of a second charge carrier. Contacts are connected to the regions of the photovoltaic cells in configurations that allow excess current to be extracted as useful energy. In one embodiment, a first contact is electrically connected to a second region of a first material, a second contact is electrically connected to a first region of the first material, a third contact is electrically connected to a first region of a second material, and a fourth contact is electrically connected to a third material. In other embodiments, the contacts may be positioned on the surfaces of the monolithic device to minimize shadowing.

This application is a continuation in part of U.S. patent application Ser. No. 12/424,658 entitled “Three Terminal Monolithic Multijunction Solar Cell”, filed Apr. 16, 2009.

### BACKGROUND

Some embodiments generally relate to the conversion of sunlight to electric current. More specifically, embodiments may relate to improved photovoltaic cells for use in conjunction with solar collectors.

A solar cell includes photovoltaic material for generating charge carriers (i.e., holes and electrons) in response to received photons. The photovoltaic material includes a p-n junction which creates an electric field within the photovoltaic material. The electric field directs the generated charge through the photovoltaic material and to elements electrically coupled thereto. Many types of solar cells are known, which may differ from one another in terms of constituent materials, structure and/or fabrication methods. A solar cell may be selected for a particular application based on its efficiency, electrical characteristics, physical characteristics and/or cost.

A multijunction solar cell generally comprises one or more monojunction solar cells (i.e., a solar cell as described above) monolithically formed on one or more other monojunction solar cells. The photovoltaic material of each of the monojunction solar cells is associated with a different bandgap. Consequently, each monojunction solar cell of the multijunction solar cell absorbs (i.e., converts) photons from different portions of the solar spectrum.

The individual monojunction solar cells of a multijunction solar cell are connected in series. The voltage developed by the multijunction solar cell is therefore equal to the sum of the voltages across each of the monojunction solar cells. However, the current flowing through the multijunction solar cell is limited to the current produced by its lowest current-producing monojunction solar cell. The excess current produced by one or more of the other monojunction solar cells is dissipated as heat, thereby wasting the excess current and elevating the cell temperature. Increased cell temperature typically results in decreased cell efficiency.

Improved monolithic multijunction solar cells are desired.

### SUMMARY

The present invention provides for a monolithic photovoltaic (PV) cell comprising a first surface and second surface and two or more PV cell materials disposed between the surfaces. The monolithic PV cell may convert solar irradiation received on the second surface and convert the irradiation into useable electrical energy. The monolithic PV cell of this invention may be comprised of a first and second PV cell material, and each material may include a first region exhibiting an excess of a first type of charge carrier and a second region of the photovoltaic material exhibiting an excess of a second type of charge carrier. The monolithic cell of this invention may also include a third PV cell material comprised of a first region of the third material exhibiting an excess of the first type of charge carrier and a second region of the third photovoltaic material exhibiting an excess of the second type of charge carrier. In some embodiments, an optional dielectric layer may be placed between two of the PV cell materials.

A first contact may be connected to the second region of the first PV cell material, a second contact may be connected to the first region of the first PV cell material, a third contact may be connected to the first region of the second PV cell material and a fourth contact may be connected to the third PV cell material. The first surface of the monolithic PV cell of this invention may be disposed between a portion of the first, second, and fourth contacts and the second region of the first PV cell material.

The construction and usage of embodiments will become readily apparent from consideration of the following specification as illustrated in the accompanying drawings, in which like reference numerals designate like parts.

### BRIEF DESCRIPTION OF THE DRAWINGS

FIG. 1 is a schematic cross section of a device according to some embodiments.

FIG. 2 is a schematic diagram of a system according to some embodiments.

FIG. 3 is a cutaway perspective view of a device according to some embodiments.

FIG. 4 is a schematic cross section of an embodiment of a device without a dielectric layer.

FIG. 5 is a schematic diagram of a system according to some embodiments.

FIG. 6 is a schematic cross section of a quadruple junction photovoltaic cell device according to some embodiments.

FIG. 7 is a schematic diagram of a system according to some embodiments.

FIG. 8 is a schematic cross section of a device according to some embodiments, whereby all cell contacts are on the back surface.

### DETAILED DESCRIPTION

The following description is provided to enable any person in the art to make and use the described embodiments and sets forth the best mode contemplated for carrying out some embodiments. Various modifications, however, will remain readily apparent to those in the art.

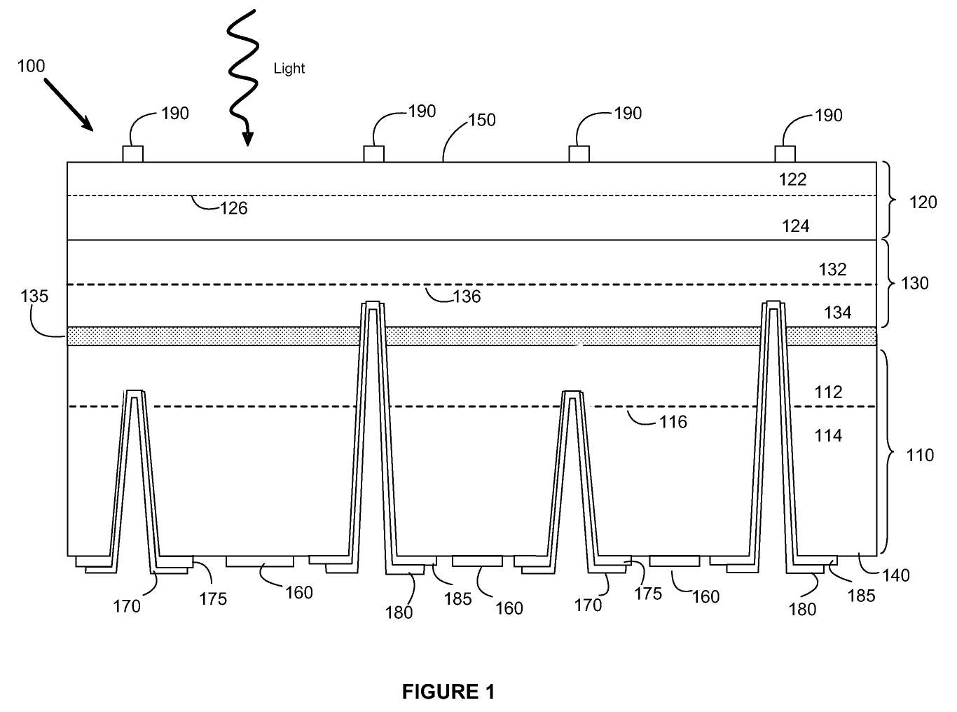

Device 100 of FIG. 1 is a monolithic multijunction photovoltaic cell according to some embodiments. Multijunction photovoltaic cell 100 includes photovoltaic cell material 110 composed of a first photovoltaic material, photovoltaic cell 120 composed of a second photovoltaic material, and photovoltaic cell 130 composed of a third photovoltaic material. Each of cells 110 through 130 includes a region (112, 122 and 132) exhibiting an excess of a first type of charge carrier (e.g., electrons or holes) and a region (114, 124 and 134) exhibiting an excess of a second type of charge carrier (e.g., holes or electrons). These regions create respective p-n junctions within each of cells 110 through 130, specifically p-n junction 116 within photovoltaic cell 110, p-n junction 126 within photovoltaic cell 120, and p-n junction 136 within photovoltaic cell 130.

First surface 140 and second surface 150 are disposed on opposite sides of device 100. Each of cells 110 through 130 are disposed between first surface 140 and second surface 150. The thickness of monolithic PV cell between first surface 140 and second surface 150 in some embodiments may be greater than 2000 angstroms thick. Second surface 150 is at least partially transparent. In this regard, photons of at least part of the sunlight spectrum may pass through second surface 150 and into device 100 during operation of device 100.

Contacts 160, 170, 180 and 190 may be used to extract current from device 100 during operation. Each of contacts 160 is electrically connected to region 114 of cell 110. Each of contacts 170 is electrically connected to region 112 of cell 110, and electrically insulated from region 114 by virtue of dielectric insulator 175. Each of contacts 180 is electrically connected to region 134 of photovoltaic cell 130, and electrically insulated from regions 112 and 114 by virtue of dielectric insulator 185. In the embodiment shown in FIG. 1, device 100 may include a dielectric layer 135 to electrically separate photovoltaic cell 130 from photovoltaic cell 110. The dielectric layer 135 may be greater than, for example, 0.1 microns thick and may be comprised of any material that impedes an electrical flow. The dielectric layer 135 may be comprised of, for example, GaAs:Cr, InP:Fe, AlGaAs: O, phosphosilicate, SiO₂, SiN₄ or borosilicate glass. A dielectric layer between individual cells in a multijunction cell enables the cells to be advantageously connected in parallel. This provides for the connection of like cells in series, allowing advantageously higher voltage operation of a string of cells.

At least a portion of each of contacts 160, 170 and 180 is disposed on the “back” of device 100. More specifically, first surface 140 is between region 114 and at least a portion of each of contacts 160, 170 and 180. Each of contacts 190 is electrically connected to region 122 of cell 120. Second surface 150, or the “front” side of device 100 through which light is received, may be between at least a portion of each of contacts 190 and region 122 of cell 120. Contacts 180, 170, and 160 may be located directly underneath contacts 190 to advantageously maximize active area material exposed to perpendicular exposure to solar radiation, while minimizing shadowing. The contacts 180, 170, and 160 may connect to specific regions in the monolithic cell by way of vias created through the device 100. Insulators 175 and 185 may prevent current leakage through other regions of the cell.

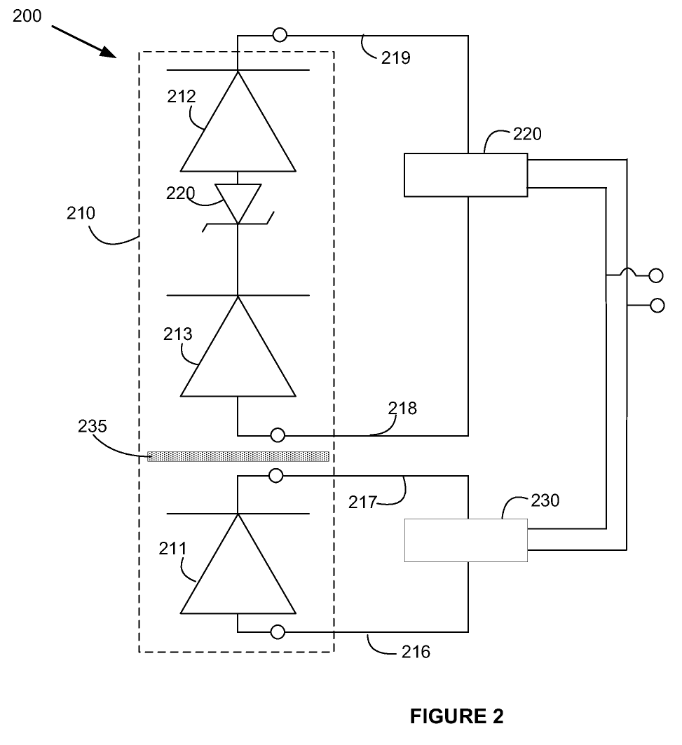

FIG. 2 is a schematic diagram of system 200 according to some embodiments. System 200 includes a schematic diagram of solar cell 210, which may be implemented by solar cell 100 of FIG. 1. In particular, diode 212 represents photovoltaic cell 120, diode 213 represents photovoltaic cell 130, and diode 211 represents photovoltaic cell 110. In the illustrated example, and according to conventional multijunction solar cell design, a first tunnel diode layer 220 may be disposed between photovoltaic cell 120 and 130. A dielectric layer 235 that may include other active, dielectric, metallization and other layers and/or components that are or may become known may be disposed between cells 211 and 213.

Terminals 216, 217, 218 and 219 of solar cell 210 represent contacts 160, 170, 180 and 190, respectively. Accordingly, the foregoing arrangement allows the extraction of current generated by photovoltaic cell 110 which exceeds the current generated by cells 120 and 130. Extraction of this excess current may increase an overall efficiency of device 100 and may lower an operating temperature of device 100 (also resulting in increased efficiency) with respect to prior arrangements. Embodiments are not limited to the arrangement of FIGS. 1 and/or 2.

An example of operation will now be provided in reference to FIG. 1. Each of the first, second and third photovoltaic materials is associated with a bandgap. The bandgap is an energy difference between the top of a material's valence band and the bottom of the material's conduction band. According to some embodiments, a bandgap associated with the first photovoltaic material of first photovoltaic cell 110 is less than a bandgap associated with the third photovoltaic material of third photovoltaic cell 130, and the bandgap associated with the third photovoltaic material of third photovoltaic cell 130 is less than a bandgap associated with the second photovoltaic material of second photovoltaic cell 120.

Surface 150 may receive light having any suitable intensity or spectra. Some photons of the received light are absorbed by second photovoltaic cell 120. For example, photons of the received light which exhibit energies greater than the bandgap associated with the second photovoltaic material enter second photovoltaic cell 120 and liberate holes in region 122 and electrons in region 124. The liberated electrons may be pulled into the region 122 and the liberated holes may be pulled into region 124 by means of an electric field established by and along p-n junction 126.

Photons of the received light which exhibit energies less than the bandgap associated with the second photovoltaic material may pass through photovoltaic cell 120 and into photovoltaic cell 130. Any of such photons which exhibit energies greater than the bandgap associated with the third photovoltaic material may liberate holes in region 132 and electrons in region 134. Again, the liberated electrons may be pulled into region 132 and the liberated holes may be pulled into region 134 by means of an electric field established by and along p-n junction 136.

The process may continue within photovoltaic cell 110 with respect to photons of the received light which exhibit energies less than the bandgaps associated with either the second photovoltaic material or the third photovoltaic material. These photons which exhibit energies greater than the bandgap associated with the first photovoltaic material liberate holes in region 112 and electrons in region 114. The liberated electrons are pulled into region 112 and the liberated holes are pulled into region 114 of photovoltaic cell 110 by means of an electric field established by and along p-n junction 116.

As described in the present Background, photovoltaic cell 110 may generate more current than either of photovoltaic cells 120 or 130. Contact 170 provides an exit path for the excess current so it may be harvested as useful energy. In some embodiments, photovoltaic cell material 110 is operated as a single junction solar cell having external contacts 160 and 170, while photovoltaic cell materials 120 and 130 are operated as a series-connected pair of cells having external contacts 180 and 190. A monolithic multijunction solar cell of this invention may transfer power to two or more inverters via separate terminal pairs (e.g., 160/170 and 180/190). This may provide for a parallel arrangement of inverters.

System 200 of FIG. 2 illustrates one example of such operation. Inverter 220 is coupled to terminals 219 and 218 in a typical series-connected multijunction cell arrangement. Inverter 230 is coupled to terminals 217 and 216 in a typical single junction cell arrangement. In some embodiments, inverter 220 is designed to operate in conjunction with the particular voltages and currents provided by series-connected cells 212 and 213, and inverter 230 is designed to operate in conjunction with the particular voltages and currents provided by cell 211. Each of inverters 220 and 230 may be coupled in parallel to each other or to one or more other single or multijunction solar cells. The outputs of inverters 220 and 230 may be connected to provide AC power to an external circuit.

A solar cell according to some embodiments may retain the spectral advantages of a conventional triple junction solar cell and may be fabricated using similar technologies. For example, various layers of solar cell 100 may be formed using molecular beam epitaxy and/or metal organic chemical vapor deposition. According to some embodiments, photovoltaic cell 110 is fabricated according to known techniques and the remaining photovoltaic cells are fabricated thereon. Each of photovoltaic cells 110 through 130 may include several layers of various photovoltaic compositions and dopings.

Any suitable materials that are or become known may be incorporated into device 100. For example, photovoltaic cell 110 may comprise Germanium or any other suitable substrate (e.g., GaAs, Si etc.). Some examples of photovoltaic cell 130 include GaAs and GaInP, while examples of photovoltaic cell 120 include AlInP, GaInP and AlGaInP. The dielectric layer 135 may be comprised of any electrically insulating material such as, GaAs:Cr, InP:Fe, AlGaAs: O, phosphosilicate, SiO₂, SiN₄ and borosilicate, or any other material known in the art.

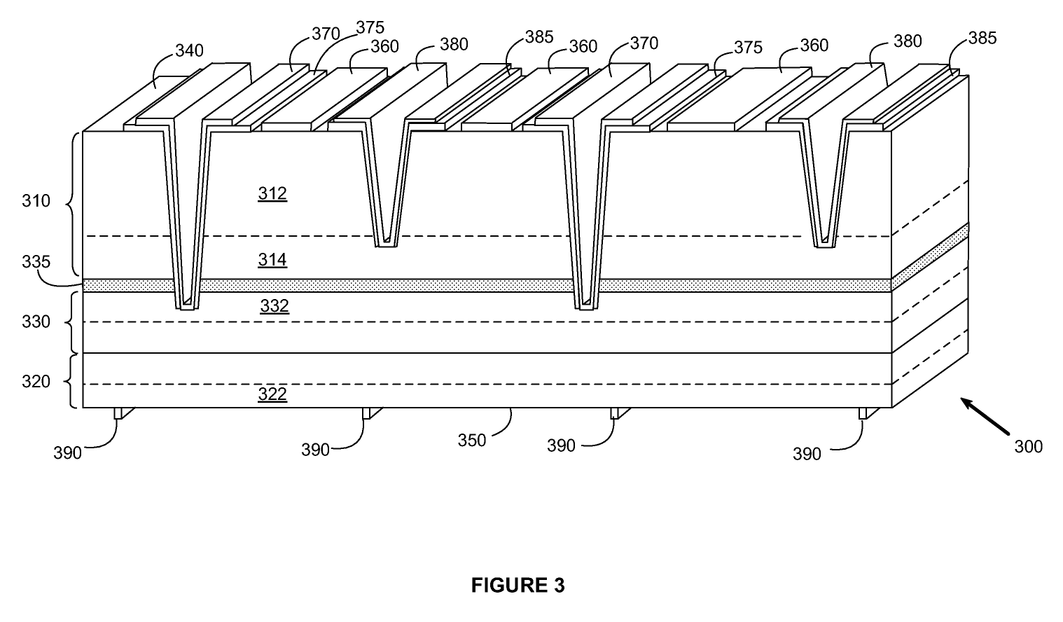

FIG. 3 is a cutaway perspective view of solar cell 300 according to some embodiments. Solar cell 300 may comprise an implementation of solar cell 100 and/or solar cell 210 according to some embodiments. The elements and operation of cell 300 may be similar to those described above with respect to cell 100. FIG. 3 illustrates a physical arrangement of contacts 360, 370, and 380 as well as dielectric insulators 375 and 385 according to some embodiments. Contacts 360 are electrically connected to region 312 of photovoltaic cell 310, and contacts 370 are electrically connected to region 332 of photovoltaic cell 330. Contacts 380 are electrically connected to region 314 of photovoltaic cell 310. The sizes and shapes of contacts 360, contacts 370, contacts 380 and dielectric insulators 375 and 385, as well as the relative positions thereof, are not limited to that shown in FIG. 3. As non-exhaustive examples, rather than the rectangular shapes that run linearly along one dimension of the cell 300, contacts 370 and dielectric insulator 375 may exhibit a square or a circular cross section in a plane parallel to second surface 350. In one embodiment of this invention, there may be a plurality of contacts 370 and 380 on surface 340, beneficially decreasing the spreading resistance of the electrical current. Dielectric layer 335 may be disposed between any two photocells, for example, photocells 310 and 330.

Contacts 390 are electrically coupled to region 322 of photovoltaic cell 320. Contacts 390, in some embodiments, are disposed over second surface 350 in a grid-like pattern to facilitate suitable collection of generated electrons. Again, any contacts described herein may exhibit any size, pattern or arrangement. Contacts 390 may be disposed directly over contacts 370 or 380 in order to beneficially minimize shading of active areas of PV cell material during direct irradiation of surface 350 of the monolithic PV cell.

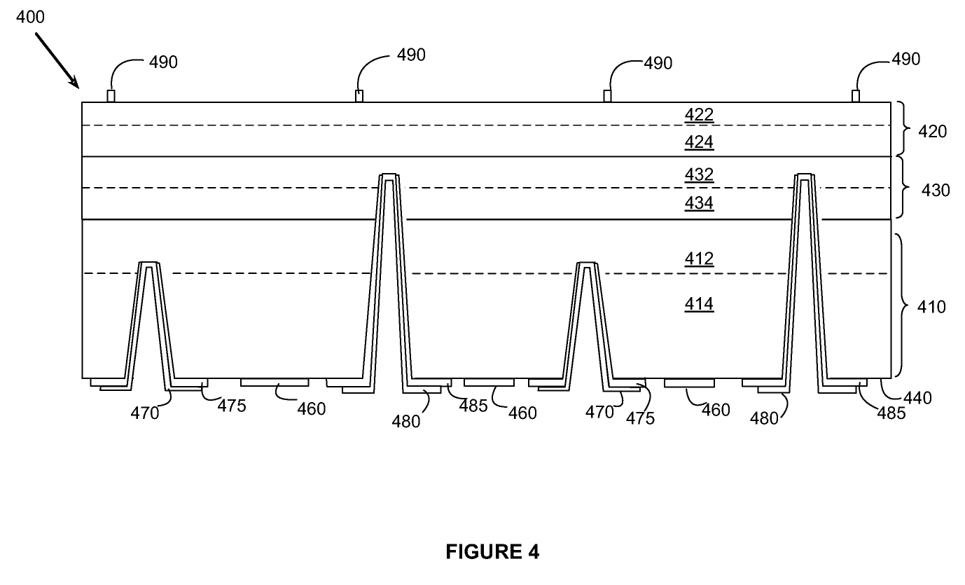

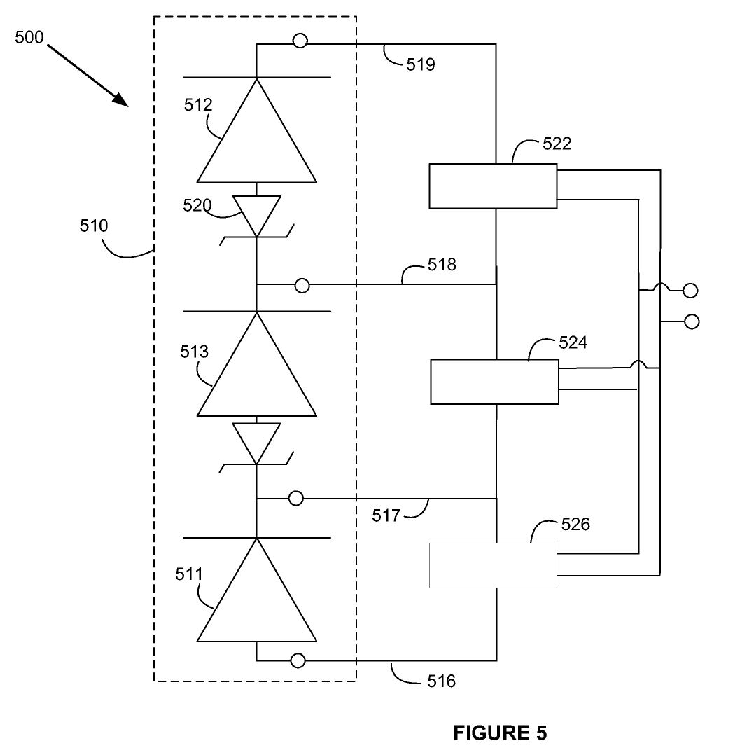

FIG. 4 is a schematic cross section of monolithic multijunction cell 400 according to some embodiments, in which a dielectric layer is not present. The elements and operation of cell 400 may be similar to those described above with respect to cell 100. Moreover, cell 400 may embody cell 510 of the electrical schematic of FIG. 5.

Contacts 470 of cell 400 are electrically connected to region 412 of cell 410. However, in contrast to cell 100 no dielectric layer is disposed between any pair of photovoltaic cells. In addition, contacts 480 extend to region 432 of photovoltaic cell 430. Such an arrangement may facilitate fabrication of contacts 470 and 480 as well as dielectric insulators 475 and 485 in some embodiments. Such an arrangement may necessitate the use of three inverters in series in order to accommodate the electrical flow from the multijunction cell. Contacts 470 may extend to any suitable degree through region 432 of cell 430. Contacts 490 and 460 may be electrically connected to regions 422 and 414 respectively.

FIG. 5 depicts a schematic diagram of an embodiment of the electronic arrangement of a multijunction solar cell of this invention, such as the embodiment of FIG. 4. System 500 illustrates one example of operation of a four terminal solar cell 510 with no insulating layer between photovoltaic cells. Inverter 522 is coupled to terminals 519 and 518 in a typical single junction cell arrangement. Inverter 524 is coupled to terminals 517 and 518 in a typical single junction cell arrangement. Inverter 526 is coupled to terminals 516 and 517 in a typical single junction cell arrangement. In some embodiments, inverter 522 is designed to operate in conjunction with the particular voltages and currents provided by series-connected cell 512, and inverter 524 is designed to operate in conjunction with the particular voltages and currents provided by cell 513. Inverter 526 is designed to operate in conjunction with the particular voltages and currents provided by cell 511. Each of inverters 522, 524, 526 may be coupled in parallel to each other or to one or more other single or multijunction solar cells. The outputs of inverters may be connected to provide AC power to an external circuit.

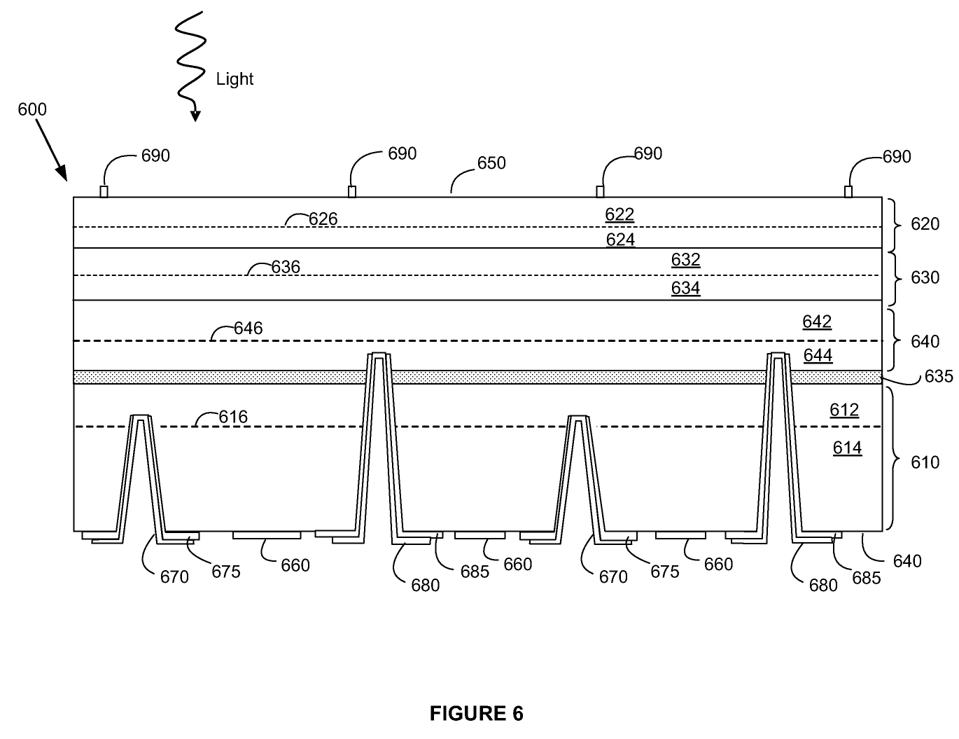

FIG. 6 depicts a schematic cross section of a monolithic multijunction photovoltaic cell according to some embodiments. Multijunction photovoltaic cell 600 includes quadruple junction photovoltaic cell 610 composed of a first photovoltaic material, photovoltaic cell 620 composed of a second photovoltaic material, photovoltaic cell 630 composed of a third photovoltaic material and photovoltaic cell 640 composed of a fourth photovoltaic material. The first through fourth photovoltaic materials may exhibit increasingly larger bandgaps for operation as described above.

Cells 610 through 640 include regions (612, 622, 632, and 642) exhibiting an excess of a first type of charge carrier (e.g., electrons or holes) and regions (614, 624, 634, and 644) exhibiting an excess of a second type of charge carrier (e.g., holes or electrons). These regions create respective p-n junction 616 within photovoltaic cell 610, p-n junction 626 within photovoltaic cell 620, p-n junction 636 within photovoltaic cell 630 and p-n junction 646 within photovoltaic cell 640.

Cells 610 through 640 are disposed between a first surface 640 and a second surface 650. The second surface 650 is at least partially transparent to accept light into cell 600 during operation. Cell 640 is electrically isolated from cell 610 by dielectric layer 635. Contacts 660 are electrically connected to region 614 of cell 610. Contacts 670 are electrically connected to region 612 of cell 610, and electrically insulated from region 614 by dielectric insulator 675. Contacts 660 are electrically connected to region 614 of cell 610. Contacts 680 are electrically connected to region 644 of cell 640 and electrically insulated from cell 610 by dielectric insulator 685. First surface 640 is disposed between region 614 and at least a portion of each of contacts 660 and 670 and 680. Contacts 690 are electrically connected to region 622 of cell 620. Second surface 650 may be between at least a portion of each of contacts 690 and region 620. Cell 600 may be formed using molecular beam epitaxy, metal organic chemical vapor deposition, and/or other suitable techniques. According to some embodiments, photovoltaic cell 610 is initially fabricated and then dielectric layer 635, as well as photovoltaic cells 640 through 620, is fabricated thereon. Contacts 660, 670, 680 and 690 may be fabricated in any suitable order using any suitable process.

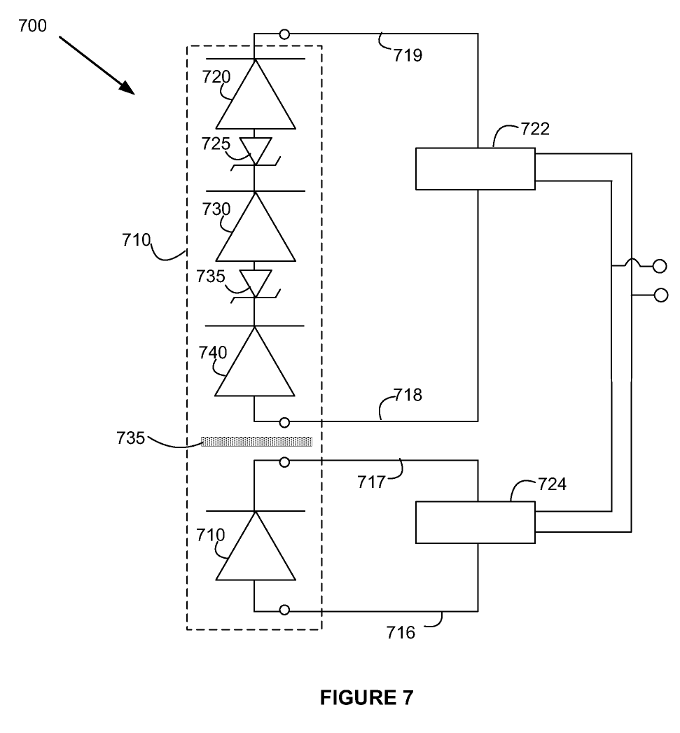

FIG. 7 is a schematic diagram of the electronic arrangement of solar cell 700 according to some embodiments. Photovoltaic cell 600 of FIG. 6 may comprise one implementation of solar cell 700. In particular, diode 720 represents photovoltaic cell 620, diode 730 represents photovoltaic cell 630, diode 740 represents photovoltaic cell 640, and diode 710 represents photovoltaic cell 610. Tunnel diode 725 represents a tunnel diode (unshown in FIG. 6) disposed between photovoltaic cells 720 and 730. Tunnel diode 735 represents a tunnel diode (unshown in FIG. 6) disposed between photovoltaic cells 730 and 740. Terminals 716, 717, 718 and 719 of solar cell 700 represent contacts 660, 670, 680 and 690 of cell 600. Contacts 660 and 670 provide for extraction of current generated by photovoltaic cell 610 which may exceed the current generated by cell 620, 630, or 640. As in the embodiments of this disclosure described above, extraction of this excess current may increase an overall efficiency of device 600 and may lower an operating temperature of device 600. Inverter 722 is coupled to terminals 719 and 718 in a typical multijunction cell arrangement. Inverter 724 is coupled to terminals 716 and 717 in a typical single junction cell arrangement. In some embodiments, inverter 722 is designed to operate in conjunction with the particular voltages and currents provided by series-connected cells 720 through 740, and inverter 724 is designed to operate in conjunction with the particular voltages and currents provided by cell 710. Each of inverters 722 and 724 may be coupled in parallel to each other or to one or more other single or multijunction solar cells. The outputs of inverters may be connected to provide AC power to an external circuit.

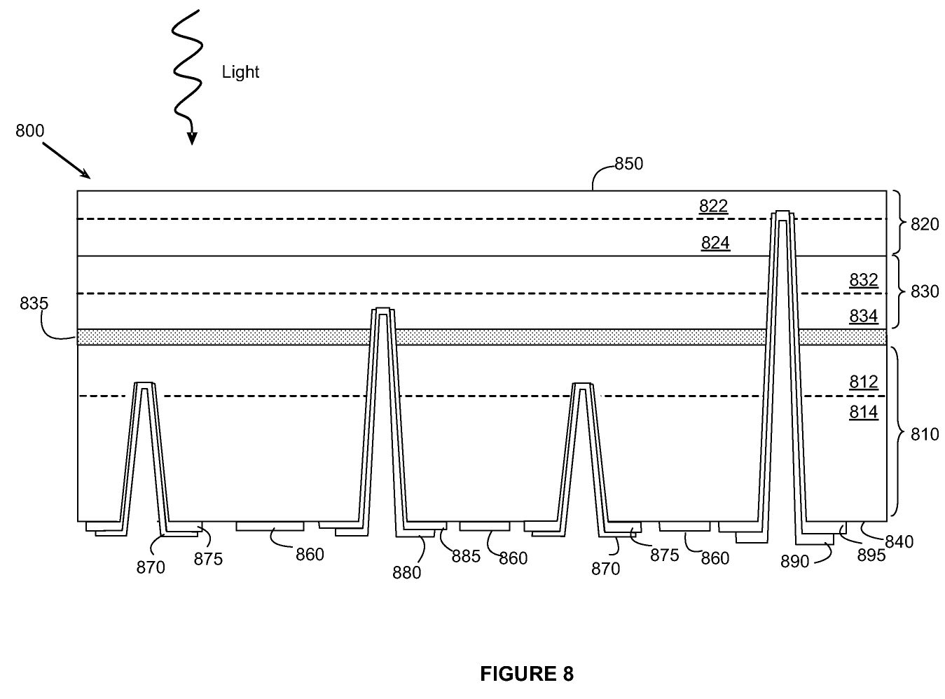

FIG. 8 is a schematic cross section of multijunction solar cell 800 showing an alternative electrical arrangement of the contacts according to some embodiments. Solar cell 800 includes photovoltaic cell materials 810 through 830 composed of respective photovoltaic materials to provide triple junction operation as described above. Similar to the foregoing arrangements, contacts 860 are electrically connected to region 814 of cell 810, and contacts 870 are electrically connected to region 812 and electrically insulated from region 814 by dielectric insulator 875. Contacts 880 are electrically connected to region 834 of cell 830 and electrically insulated from cell 810 by dielectric insulator 885. Dielectric layer 835 prevents electrical contact between cell 810 and cell 830. First surface 840 is between region 814 and at least a portion of each of contacts 860, 880, 870 and 890. In this embodiment each terminal contact is located below surface 850, beneficially providing for maximum exposure of surface 850 to solar irradiation. Each of contacts 890 is electrically connected to region 822 of cell 820 and electrically insulated from the other cells by dielectric insulator 895. Accordingly, solar cell 800 may be accurately represented by the schematic diagram of solar cell 210 of FIG. 2.

In contrast to the arrangements described above, first surface 840 is between at least a portion of each of contacts 890 and region 812 of cell 810. That is, at least a portion of each of contacts 860, 880, 870 and 890 is disposed on the “back” of cell 800. As a result, front surface 850 is not obscured by contacts and is able to receive light over its entire area. Taken alone, this change may increase an overall efficiency of cell 800 in comparison to cell 100. However, this increase may be offset by a decrease in efficiency due to a decreased total volume of photovoltaic material. The actual decrease in total volume may be controlled based on a size, shape and number of contacts 870, 880, and 890. Regardless of the effect on cell efficiency, the presence of all contacts on the back side of cell 800 may facilitate electrical connection thereof to external circuitry.

The several embodiments described herein are solely for the purpose of illustration. Embodiments may include any currently or hereafter-known versions of the elements described herein. Therefore, persons skilled in the art will recognize from this description that other embodiments may be practiced with various modifications and alterations.

What is claimed is:

1. A monolithic photovoltaic cell comprising:
a first surface;
a second surface to receive light;
a first photovoltaic cell between the first surface and the second surface, the first photovoltaic cell comprising a first region of a first photovoltaic material exhibiting an excess of a first type of charge carrier and a second region of the first photovoltaic material exhibiting an excess of a second type of charge carrier;
a second photovoltaic cell between the first surface and the second surface, the second photovoltaic cell comprising a first region of a second photovoltaic material exhibiting an excess of the first type of charge carrier and a second region of the second photovoltaic material exhibiting an excess of the second type of charge carrier;
a third photovoltaic cell between the first surface and the second surface, the third photovoltaic cell comprising a first region of a third photovoltaic material exhibiting an excess of the first type of charge carrier and a second region of the third photovoltaic material exhibiting an excess of the second type of charge carrier;
a first contact electrically connected to the second region of the first photovoltaic material;
a second contact electrically connected to the first region of the first photovoltaic material;
a third contact electrically connected to the first region of the second photovoltaic material; and
a fourth contact electrically connected to the third photovoltaic material;
wherein the first surface is between at least a portion of the first contact and the second region of the first photovoltaic material;
wherein the first surface is between at least a portion of the second contact and the second region of the first photovoltaic material; and
wherein the first surface is between at least a portion of the fourth contact and the second region of the first photovoltaic material.

2. The monolithic photovoltaic cell of claim 1 wherein the second and fourth contacts comprise a plurality of contact vias.

3. The monolithic photovoltaic cell of claim 1 further comprising a dielectric layer disposed between the second region of the third photovoltaic cell and the first region of the first photovoltaic cell, wherein the fourth contact is electrically connected to the second region of the third photovoltaic material.

4. The monolithic photovoltaic cell of claim 3 wherein the dielectric layer is greater than 0.1 microns in thickness.

5. The monolithic photovoltaic cell of claim 3 wherein the dielectric layer comprises a material selected from the group consisting of GaAs:Cr, InP:Fe, AlGaAs: O, phosphosilicate, SiO₂, SiN₄ and borosilicate glass.

6. The monolithic photovoltaic cell of claim 1,
wherein the first photovoltaic material is associated with a first bandgap;
wherein the third photovoltaic material is associated with a third bandgap greater than the first bandgap;
wherein the second photovoltaic material is associated with a second bandgap greater than the third bandgap;
wherein the second region of the second photovoltaic material is between the first region of the second photovoltaic material and the first region of the third photovoltaic material; and
wherein the second region of the third photovoltaic material is between the first region of the third photovoltaic material and the first region of the first photovoltaic material.

7. The monolithic photovoltaic cell of claim 1 wherein the second surface is between at least a portion of the third contact and the first region of the second photovoltaic material.

8. The monolithic photovoltaic cell of claim 7 wherein a portion of the first, second, and fourth contacts are disposed directly underneath the third contact.

9. The monolithic photovoltaic cell of claim 1 wherein the first surface is between at least a portion of the third contact and the second region of the first photovoltaic material.

10. The monolithic photovoltaic cell of claim 3 further comprising:
a first inverter electrically connected to the first contact and to the second contact; and
a second inverter electrically connected to the fourth contact and to the third contact;
wherein the fourth contact is electrically connected to the second region of the third photovoltaic material.

11. The monolithic photovoltaic cell of claim 1 further comprising:
a first inverter electrically connected to the first contact and to the second contact;
a second inverter electrically connected to the second contact and to the fourth contact; and
a third inverter electrically connected to the third contact and to the fourth contact.

12. The monolithic photovoltaic cell of claim 1 wherein the thickness of the cell between the first surface and the second surface is greater than 2000 angstroms.

13. The monolithic photovoltaic cell of claim 1 wherein the first photovoltaic material comprises germanium.

14. A monolithic photovoltaic cell comprising:
a first surface;
a second surface to receive light;
a first photovoltaic cell between the first surface and the second surface, the first photovoltaic cell comprising a first region of a first photovoltaic material exhibiting an excess of a first type of charge carrier and a second region of the first photovoltaic material exhibiting an excess of a second type of charge carrier;
a second photovoltaic cell between the first surface and the second surface, the second photovoltaic cell comprising a first region of a second photovoltaic material exhibiting an excess of the first type of charge carrier and a second region of the second photovoltaic material exhibiting an excess of the second type of charge carrier;
a first contact electrically connected to the second region of the first photovoltaic material;
a second contact electrically connected to the first region of the first photovoltaic material;
a third contact electrically connected to the first region of the second photovoltaic material; and
a fourth contact electrically connected to the second region of the second photovoltaic material;
wherein the first surface is between at least a portion of the first contact and the second region of the first photovoltaic material;
wherein the first surface is between at least a portion of the second contact and the second region of the first photovoltaic material; and
wherein the first surface is between at least a portion of the fourth contact and the second region of the first photovoltaic material.

15. A method of constructing a monolithic photovoltaic cell, the monolithic photovoltaic cell comprising a first photovoltaic cell having first and second regions of a first photovoltaic material, a second photovoltaic cell having first and second regions of a second photovoltaic material, and a third photovoltaic cell having first and second regions of a third photovoltaic material, the method comprising:
electrically connecting a first contact to the second region of the first photovoltaic material;
electrically connecting a second contact to the first region of the first photovoltaic material;
electrically connecting a third contact to the first region of the second photovoltaic material; and
electrically connecting a fourth contact to the first region of the third photovoltaic material;
providing a first surface between at least a portion of the first contact and the second region of the first photovoltaic material, and between at least a portion of the second contact and the second region of the first photovoltaic material; and
providing a second surface to receive light into the second photovoltaic cell.

16. The method according to claim 15,
wherein the first photovoltaic material is associated with a first bandgap,
wherein the second photovoltaic material is associated with a second bandgap greater than the first bandgap, and
wherein the second region of the second photovoltaic material is between the first region of the second photovoltaic material and the first region of the first photovoltaic material.

17. The method according to claim 15 further comprising the step of placing a dielectric layer between the first photovoltaic material and the third photovoltaic material.

18. The method according to claim 15,
wherein the first photovoltaic material is associated with a first bandgap,
wherein the third photovoltaic material is associated with a third bandgap greater than the first bandgap,
wherein the second photovoltaic material is associated with a second bandgap greater than the third bandgap,
wherein the second region of the second photovoltaic material is between the first region of the second photovoltaic material and the first region of the third photovoltaic material, and
wherein the second region of the third photovoltaic material is between the first region of the third photovoltaic material and the first region of the first photovoltaic material.

19. The method according to claim 15,
wherein the second surface is between at least a portion of the third contact and the first region of the second photovoltaic material.

20. The method according to claim 15,
wherein the first surface is between at least a portion of the third contact and the second region of the first photovoltaic material.
